(19) United States
(12) Patent Application Publication
(10) Pub. No.: US 2022/0263286 A1
(43) Pub. Date: Aug. 18, 2022

(54) HIGH KAPPA SEMICONDUCTOR LASERS

(71) Applicant: MACOM Technology Solutions Holdings, Inc., Lowell, MA (US)

(72) Inventor: Malcolm R. Green, Lansing, NY (US)

(73) Assignee: MACOM Technology Solutions Holdings, Inc., Lowell, MA (US)

(21) Appl. No.: 17/176,968

(22) Filed: Feb. 16, 2021

(51) Int. Cl. H01S 5/028; H01S 5/12

(52) U.S. Cl. CPC H01S 5/0287; H01S 5/124; H01S 5/1212

(57) ABSTRACT

A semiconductor laser may include an active region having a longitudinal axis, a rear facet end and a front facet end. The front facet end emitting an output beam of the semiconductor laser. The semiconductor laser may include a plurality of diffraction gratings positioned along the longitudinal axis of the active region. The plurality of diffraction gratings including a first diffraction grating positioned proximate the rear facet end of the active region and at least one additional diffraction grating positioned longitudinally between the first diffraction grating and the front facet. The first diffraction grating having a first kappa value and the at least one additional diffraction grating having at least a second kappa value, the first kappa value being greater than the second kappa value.

### FIELD

The present disclosure relates to semiconductor lasers and in particular to distributed feedback (DFB) semiconductor lasers having a high kappa grating proximate a rear of a laser.

### BACKGROUND

Referring to FIGS. 1 and 2, a conventional semiconductor wafer 10 having a substrate 11 and a plurality of distributed feedback (DFB) lasers 12 formed thereon is represented. Conventional DFB lasers 12 formed on wafer 10 suffer from back facet grating phase variation which causes unpredictable yields. Referring to FIG. 1, the distribution of good DFB lasers 12 (solid oval) and poor DFB lasers 12 (open ovals) on a portion of wafer 10 is shown. This distribution is a function of the relative alignment of the e-beam lithography defining the grating and the conventional lithography defining the position of the facet.

Preferably, the quantity of good DFB lasers 12 (solid oval) would be increased for multiple reasons. First, to increase the yield of good lasers produced from the manufacturing process. Second, in the case of a laser array formed by consecutive side-by-side lasers 12 positioned side-by-side on substrate 11, there is a need to have consecutive lasers 12 which are of good quality.

### SUMMARY

In an exemplary embodiment of the present disclosure, a semiconductor laser is provided. The semiconductor laser comprising: an active region having a longitudinal axis, a rear facet end, and a front facet end, the front facet end emitting an output beam of light from the semiconductor laser; and a plurality of diffraction gratings positioned along the longitudinal axis of the active region. The plurality of diffraction gratings including a first diffraction grating positioned proximate the rear facet end of the active region and at least one additional diffraction grating positioned longitudinally between the first diffraction grating and the front facet end, the first diffraction grating having a first kappa value and the at least one additional diffraction grating having at least a second kappa value, the first kappa value being greater than the second kappa value.

In an example thereof, the first kappa value is at least 80/cm. In a variation thereof, the first kappa value is at least 100/cm.

In another example thereof, the first kappa value is in a range of 80/cm to 300/cm and the second kappa value is in a range of 10/cm to 50/cm. In a variation thereof, the second kappa value is in a range of 20/cm to 50/cm. In another variation thereof, the second kappa value is in a range of 20/cm to 40/cm. In a further variation thereof, the second kappa value is in a range of 10/cm to 40/cm. In a still further variation thereof, the first kappa value is in a range of 80/cm to 300/cm.

In a further example thereof, the first kappa value is at least 80/cm and the second kappa value is in a range of 10/cm to 50/cm.

In yet another example thereof, a ratio of the first kappa value to the second kappa value is 1.5 to 20.

In still another example thereof, a ratio of the first kappa value to the second kappa value is 1.6 to 20.

In yet a further example thereof, a ratio of the first kappa value to the second kappa value is 2 to 20.

In yet a still further example thereof, the first diffraction grating is a uniform grating.

In a further still example thereof, the at least one additional diffraction grating includes a quarter wavelength shift (QWS) grating.

In a further yet example thereof, the at least one additional diffraction grating includes a chirped grating.

In a further still example thereof, the at least one additional diffraction grating includes an asymmetric corrugation pitch modulated (ACPM) grating system. In a variation thereof, the asymmetric corrugation pitch modulated (ACPM) grating system includes a rear uniform grating positioned longitudinally proximate the first grating, a front uniform grating positioned longitudinally proximate the front facet end, and at least a third grating positioned longitudinally between the rear uniform grating and the front uniform grating, the rear uniform grating, the third grating, and the front uniform grating are contiguous. In a variation thereof, the first grating has a first pitch, the rear uniform grating has a second pitch, the third grating has a third pitch, and the front uniform grating has a fourth pitch, the third pitch being different from the first pitch, the second pitch, and the fourth pitch.

In yet another still example thereof, the at least one additional diffraction grating includes a non-contiguous asymmetric corrugation pitch modulated grating system. In a variation thereof, the non-contiguous asymmetric corrugation pitch modulated grating system includes a rear uniform grating positioned longitudinally proximate the first diffraction grating, a front uniform grating positioned longitudinally proximate the front facet end, and at least a third grating positioned longitudinally between the rear uniform grating and the front uniform grating, at least one of the rear uniform grating and the front uniform grating is longitudinally separated relative to the third grating by a region. In another variation thereof, the non-contiguous asymmetric corrugation pitch modulated grating system includes a rear uniform grating positioned longitudinally proximate the first diffraction grating, a front uniform grating positioned longitudinally proximate the front facet end, and at least a third grating positioned longitudinally between the rear uniform grating and the front uniform grating, the rear uniform grating and the third grating are :longitudinally separated by a first region and the front uniform grating and the third grating are longitudinally separated by a second region. In a variation thereof, the first grating has a first pitch, the rear uniform grating has a second pitch, the third grating has a third pitch, and the front uniform grating has a fourth pitch, the third pitch being different from the first pitch, the second pitch, and the fourth pitch.

In yet still a further example thereof, the at least one additional diffraction grating provides a continuously variable pitch between the first grating and the front facet.

In a further example thereof, the semiconductor laser further comprises a first reflection coating provided on the front facet end of the active region having a reflectivity of less than 5% and a second reflection coating provided on the rear facet end of the active region having a reflectivity of less than 5%.

In another exemplary embodiment of the present disclosure, a semiconductor laser array is provided. The semiconductor laser array comprising: a semiconductor substrate; and a plurality of semiconductor lasers formed on the semiconductor substrate. Each of the plurality of semiconductor lasers comprising: an active region having a longitudinal axis, a rear facet end, and a front facet end, the front facet end emitting an output beam of the semiconductor laser; and a plurality of diffraction gratings positioned along the longitudinal axis of the active region. The plurality of diffraction grating including a first diffraction grating positioned proximate the rear facet end of the active region and at least one additional diffraction grating positioned longitudinally between the first diffraction grating and the front facet end, the first diffraction grating having a first kappa value and the at least one additional diffraction grating having at least a second kappa value, the first kappa value being greater than the second kappa

In an example thereof, the first kappa value is at least 80/cm. In a variation thereof, the first kappa value is at least 100/cm.

In another example thereof, the first kappa value is in a range of 80/cm to 300/cm and the second kappa value is in a range of 10/cm to 50/cm. In a variation thereof, the second kappa value is in a range of 20/cm to 50/cm. In another variation thereof, the second kappa value is in a range of 20/cm to 40/cm. In a further variation thereof, the second kappa value is in a range of 10/cm to 40/cm. In a still further variation thereof, the first kappa value is in a range of 80/cm to 300/cm.

In a further example thereof, the first kappa value is at least 80/cm and the second kappa value is in a range of 10/cm to 50/cm.

In yet another example thereof, a ratio of the first kappa value to the second kappa value is 1.5 to 20.

In still another example thereof, a ratio of the first kappa value to the second kappa value is 1.6 to 20.

In yet a further example thereof, a ratio of the first kappa value to the second kappa value is 2 to 20.

In yet a still further example thereof, the first diffraction grating is a uniform grating.

In a further still example thereof, the at least one additional diffraction grating includes a quarter wavelength shift (QWS) grating.

In a further yet example thereof, the at least one additional diffraction grating includes a chirped grating.

In a further still example thereof, the at least one additional diffraction grating includes an asymmetric corrugation pitch modulated (ACPM) grating system. In a variation thereof, the asymmetric corrugation pitch modulated (ACPM) grating system includes a rear uniform grating positioned longitudinally proximate the first grating, a front uniform grating positioned longitudinally proximate the front facet end, and at least a third grating positioned longitudinally between the rear uniform grating and the front uniform grating, the rear uniform grating, the third grating, and the front uniform grating are contiguous. In a variation thereof, the first grating has a first pitch, the rear uniform grating has a second pitch, the third grating has a third pitch, and the front uniform grating has a fourth pitch, the third pitch being different from the first pitch, the second pitch, and the fourth pitch.

In yet another still example thereof, the at least one additional diffraction grating includes a non-contiguous asymmetric corrugation pitch modulated grating system. In a variation thereof, the non-contiguous asymmetric corrugation pitch modulated grating system includes a rear uniform grating positioned longitudinally proximate the first diffraction grating, a front uniform grating positioned longitudinally proximate the front facet end, and at least a third grating positioned longitudinally between the rear uniform grating and the front uniform grating, at least one of the rear uniform grating and the front uniform grating is longitudinally separated relative to the third grating by a region. in another variation thereof, the non-contiguous asymmetric corrugation pitch modulated grating system includes a rear uniform grating positioned longitudinally proximate the first diffraction grating, a front uniform grating positioned longitudinally proximate the front facet end, and at least a third grating positioned longitudinally between the rear uniform grating and the front uniform grating, the rear uniform grating and the third grating are longitudinally separated by a first region and the front uniform grating and the third grating are longitudinally separated by a second region. In a variation thereof, the first grating has a first pitch, the rear uniform grating has a second pitch, the third grating has a third pitch, and the front uniform grating has a fourth pitch, the third pitch being different from the first pitch, the second pitch, and the fourth pitch.

In yet still a further example thereof, the at least one additional diffraction grating provides a continuously variable pitch between the first grating and the front facet.

In a further example thereof each of the semiconductor lasers further comprises a first reflection coating provided on the front facet end of the active region having a reflectivity of less than 5% and a second reflection coating provided on the rear facet end of the active region having a reflectivity of less than 5%.

### BRIEF DESCRIPTION 17 THE DRAWINGS

The above-mentioned and other features and advantages of this disclosure, and the manner of attaining them, will become more apparent and will be better understood by reference to the following description of exemplary embodiments taken in conjunction with the accompanying drawings, wherein:

FIG. 1 illustrates a representative view of a conventional semiconductor wafer having a plurality of DFB lasers formed thereon;

FIG. 2 illustrates a representative view of the vertical cross-section of two respective DFB lasers formed on the semiconductor wafer of FIG. 1;

FIG. 3 illustrates a representative view of the vertical cross-section of an exemplary DFB laser having a high kappa grating positioned proximate a rear facet of the laser and one or more low kappa gratings positioned between the high kappa grating and a front facet of the laser;

FIG. 4 illustrates a representative view of the vertical cross-section of an exemplary DFB laser having a high kappa grating positioned proximate a rear facet of the laser and a low kappa grating positioned between the high kappa grating and a front facet of the laser;

FIG. 5 illustrates a representative view of the vertical cross-section of an exemplary DFB laser having a high kappa grating positioned proximate a rear facet of the laser and a low kappa quarter wave shifted grating positioned between the kappa grating and a front facet of the laser;

FIG. 6 illustrates a representative view of the vertical cross-section of an exemplary DFB laser having a high kappa grating positioned proximate a rear facet of the laser and a low kappa chirped grating positioned between the high kappa grating and a front facet of the laser;

FIG. 7 illustrates a representative view of the vertical cross-section of an exemplary DFB laser having a high kappa grating positioned proximate a rear facet of the laser and a low kappa asymmetric corrugation pitch modulated grating system positioned between the high kappa grating and a front facet of the laser;

FIG. 8 illustrates a representative view of the vertical cross-section of an exemplary DFB laser having a high kappa grating positioned proximate a rear facet of the laser and a low kappa asymmetric corrugation pitch modulated non-contiguous grating system positioned between the high kappa grating and a front facet of the laser;

FIG. 9 illustrates a representative view of the vertical cross-section of an exemplary DFB laser having a first structural configuration a high kappa grating positioned proximate a rear facet of the laser and a low kappa grating system positioned between the high kappa grating and a front facet of the laser;

FIG. 10 illustrates a representative view of the vertical cross-section of an exemplary DFB laser having a second structural configuration a high kappa grating positioned proximate a rear facet of the laser and a low kappa grating system positioned between the high kappa grating and a front facet of the laser;

FIG. 11 illustrates a representative view of the vertical cross-section of an exemplary DFB laser having a third structural configuration a high kappa grating positioned proximate a rear facet of the laser and a low kappa grating system positioned between the high kappa grating and a front facet of the laser; and

FIG. 12 illustrates a representative top view of an exemplary DFB laser having a fourth structural configuration a high kappa grating positioned proximate a rear facet of the laser and a low kappa grating system positioned between the high kappa grating and a front facet of the laser.

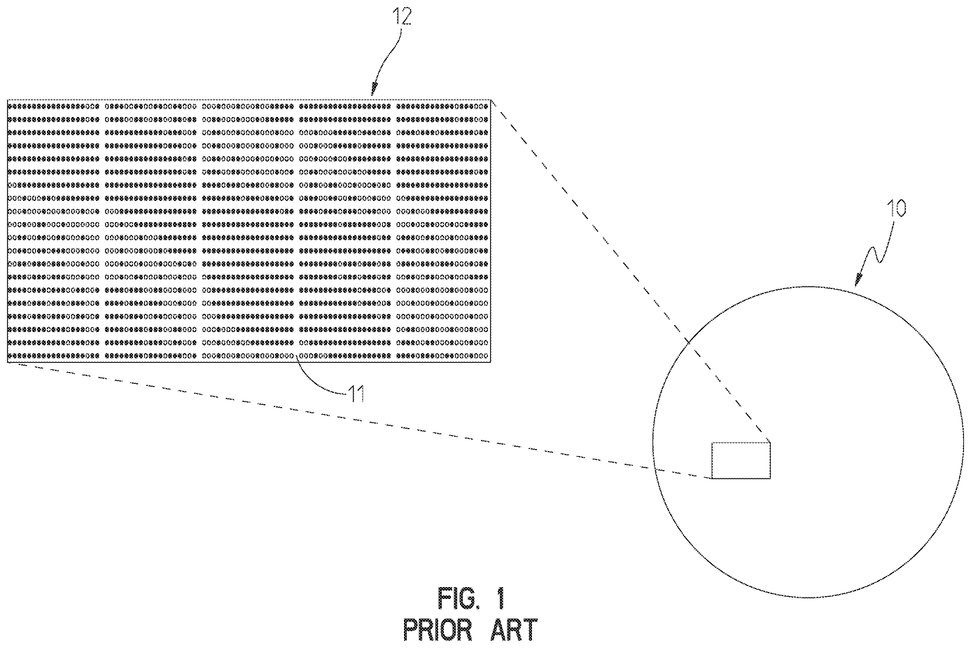

Corresponding reference characters indicate corresponding parts throughout the several views. The exemplification set out herein illustrates an exemplary embodiment of the invention and such exemplification is not to be construed as limiting the scope of the invention in any manner.

### DETAILED DESCRIPTION OF THE DRAWINGS

For the purposes of promoting an understanding of the principles of the present disclosure, reference is now made to the embodiments illustrated in the drawings, which are described below. The embodiments disclosed herein are not intended to be exhaustive or limit the present disclosure to the precise form disclosed in the following detailed description. Rather, the embodiments are chosen and described so that others skilled in the art may utilize their teachings. Therefore, no limitation of the scope of the present disclosure is thereby intended. Corresponding reference characters indicate corresponding parts throughout the several views.

The terms “couples”, “coupled”, “coupler” and variations thereof are used to include both arrangements wherein the two or more components are in direct physical contact and arrangements wherein the two or more components are not in direct contact with each other (e.g., the components are “coupled” via at least a third component), but yet still cooperate or interact with each other.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

In some instances throughout this disclosure and in the claims, numeric terminology, such as first, second, third, and fourth, is used in reference to various components or features. Such use is not intended to denote an ordering of the components or features. Rather, numeric terminology is used to assist the reader in identifying the component or features being referenced and should not be narrowly interpreted as providing a specific order of components or features.

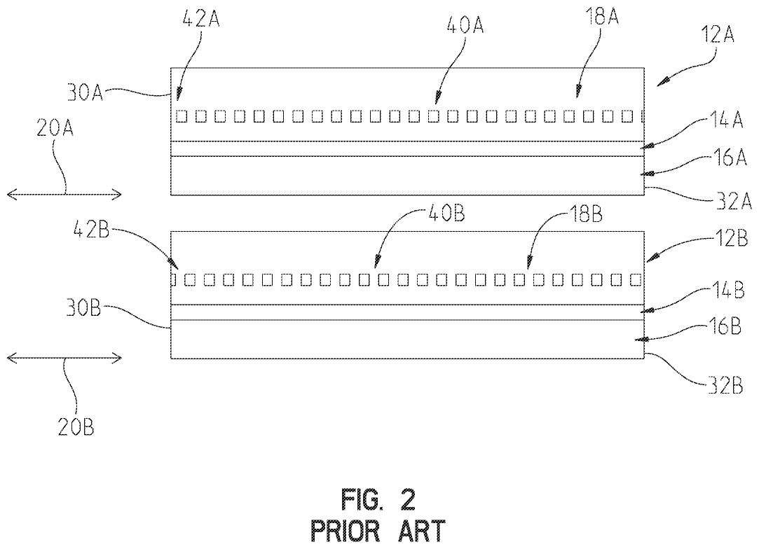

Referring to FIG. 2, a pair of conventional semiconductor DFB lasers 12A and 12B are represented. Each laser 12 includes an active layer 14A, 14B, an n-type cladding layer 16A, 16B, and a p-type cladding layer 18A,18B. Active layer 14A, 14B has a longitudinal axis 20A, 20B. Active layer 14A, 1413 is bounded in a longitudinal direction by a rear facet 30A, 30B and a front facet 32A, 328. Rear facet 30A, 30B has a high-reflectivity coating provided. thereon. Exemplary high-reflectivity coatings reflect 70% or more of incident light. Front facet 32A, 32B has a low-reflectivity coating provided thereon. Exemplary low-reflectivity coatings reflect up to 5% of incident light.

Lasers 12A, 12B include a diffraction grating 40A, 4013 along longitudinal axis 20A, 20B. Looking at region 42A, 42B proximate rear facet 30A, 30B, diffraction grating 40A, 40B has a different gap from rear facet 30A, 3013. This difference in spacing cannot be controlled by existing fabrication methods. For example, for a grating 40A, 40B having a 200 nanometer (nm) period, the alignment of the grating tooth proximate to rear facet 30A, 30B must be aligned and controlled to better than 50 nm. Failure to do so results in reduced yield of functional lasers on the wafer 10. Further, this difference in spacing affects the relative phases of the light reflected by the facet and the light reflected by the grating, which in turn affects the performance of the lasers.

Referring to FIG, 3, a semiconductor DM laser 100 is represented. Laser 100 is formed on a semiconductor substrate 101 as is known in the art. Further, as is common practice, a plurality of lasers 100 are formed side-by-side on substrate 101. Typically, a portion of the substrate 101 and a respective laser are broken off from the remainder to provide a single laser unit. However, a larger portion of substrate 101 containing multiple side-by-side lasers may be broken off as a unit. The multiple side-by-side lasers 100 forming a laser array.

Laser 100 includes an active layer 102, an n-type cladding layer 104, and a p-type cladding layer 106. Each of active layer 102, n-type cladding layer 104, and p-type cladding layer 106 extend in a longitudinal axis 110 from a front facet 112 of laser 100 to a rear facet 114 of laser 100. Laser 100 includes a grating system 120 in p-type cladding layer 106 which extends along the longitudinal direction 110 of laser 100. In embodiments, grating system 120 extends from front facet 112 of laser 100 to rear facet 114 of laser 100. In embodiments, grating system 120 does not extend to at least one of front facet 112 and rear facet 114, but rather leaves a gap over a portion of active layer 102 proximate to at least one of front facet 112 and rear facet 114. In embodiments, n-type cladding layer 104 is positioned above active layer 102 and p-type cladding layer 106 is positioned below active layer 102.

Grating system 120 comprises multiple gratings. In embodiments, grating system 120 is continuous from a first grating positioned proximate to rear facet 114 of laser 100 to a second grating positioned proximate to front facet 112. of laser 100. In embodiments, grating system 120 is non-contiguous from a first grating positioned proximate to rear facet 114 of laser 100 to a second grating positioned proximate to front facet 112 of laser 100. In embodiments, grating system 120 may be positioned below active layer 102.

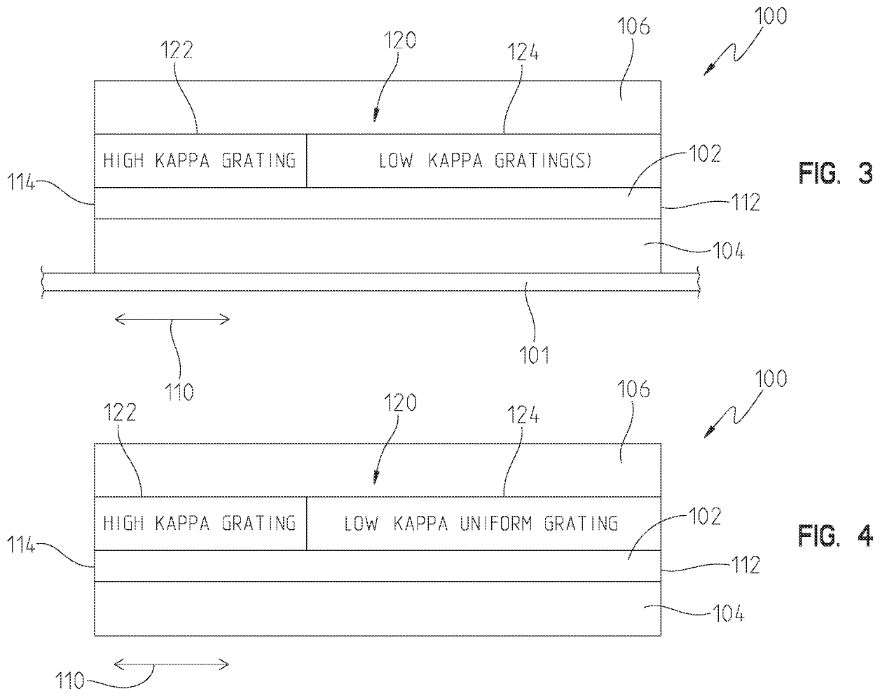

As shown in FIG. 3, grating system 120 includes a high kappa grating 122 positioned proximate to rear facet 114 of laser 100 and one or more lower kappa gratings 124 positioned longitudinally between high kappa grating 122 and front facet 112 of laser 100. As referred to in the art, the kappa value of a grating is the coupling coefficient of the grating. By having a high kappa grating positioned proximate to rear facet 114 of laser 100, the coupling strength of grating system 120 is increased in this region of laser 100. The high kappa grating 122. acts as a high reflectively mirror. In embodiments, high kappa grating 122 is fabricated at the same time as the one or more lower kappa gratings 124 so the phase of the reflection from the high kappa grating 122 is known and the performance of laser 100 is assured. This results in increased yield for the lasers 100 formed on semiconductor wafer 10 and the performance of adjacent lasers 100 on semiconductor wafer 10 to be used in laser arrays. In embodiments, each of front facet 112 and rear facet 114 includes a low reflectivity coating to avoid variation in phase of reflection of the light in active layer 102.

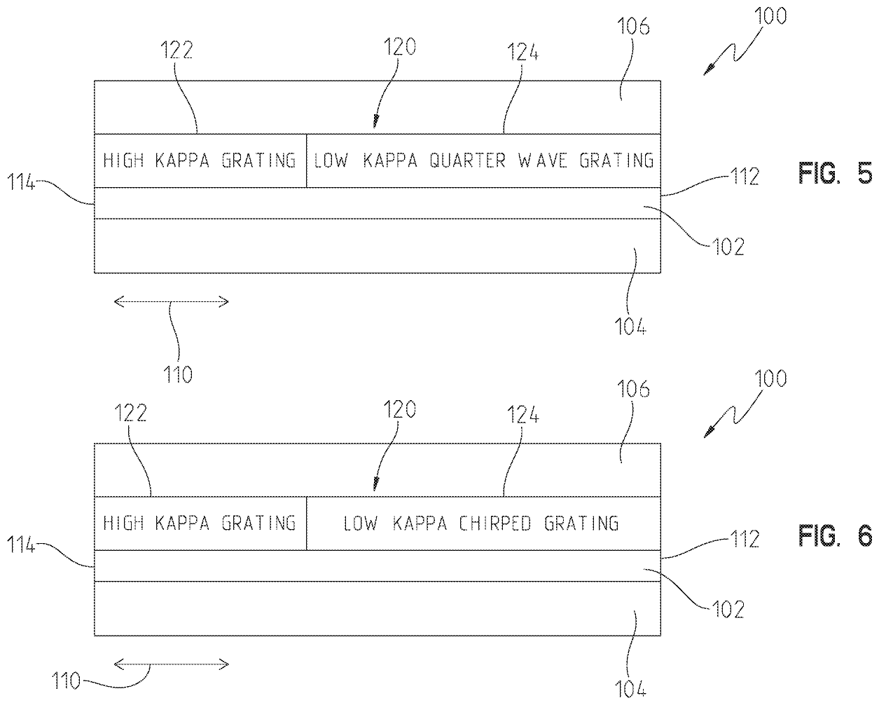

The kappa values of high kappa grating 122 of grating system 120 and lower kappa grating(s) 124 of grating system 120 and the ratio of the kappa value of high kappa grating 122 of grating system 120 to the kappa value of lower kappa grating 124 of grating system 120 effects various characteristics of laser 100, such as the threshold current, slope, wavelength, and the side mode suppression ratio SMSR) of laser 100, Laser 1.00 was simulated at various kappa values for high kappa grating 122 and lower kappa grating 124 of grating system 120 with high kappa grating 122 being a uniform grating and lower kappa grating 124 being a quarter wavelength shift (QWS) grating, as illustrated in FIG. 5. The quarter wave shift grating includes a first grating region and a second grating region, each having a constant grating pitch and depth, The first grating region and the second grating region are joined with a phase jump of π at the interface between the first grating structure and the second grating structure. Each of high kappa grating 122 and lower kappa grating 124 had an exemplary pitch of 203 nanometers (μm). The exemplary longitudinal length of high kappa grating 122 was 100 micrometers (μm) and the exemplary longitudinal length of lower kappa grating 124 was 799 μm with the phase jump being positioned closer to a rear end of lower kappa grating 124 proximate high kappa grating 122, for example at 266 nm from the rear end of lower kappa grating 124. Other dimensions may be implemented for laser 100.

Based on the simulations, an advantage among others of having a kappa value of high kappa grating 122 being at least 100/cm is a threshold current for laser 100 of 25 milliamps (mA). An advantage among others of having a kappa value of high kappa grating 122 being in a range of 80/cm to 200/cm and a kappa value of lower kappa grating 124 being in a range of 10/cm to 50/cm is a threshold current for laser 100 of less than 25 milliamps (mA) (resulting in a ratio of the kappa value of high kappa grating 122 to the kappa value of lower kappa grating 124 being in a range of 1.6 to 20). An advantage among others of having a kappa value of high kappa grating 122 being in a range of 80/cm to 300/cm and a kappa value of lower kappa grating 124 being in a range of 10/cm to 40/cm is a slope for laser 100 of at least 0.1 milliwatts per milli amp (mW/mA) (resulting in a ratio of the kappa value of high kappa grating 122 to the kappa value of lower kappa grating 124 being in a range of 2 to 20). An advantage among others of having a kappa value of high kappa grating 122 being in a range of 80/cm to about 200/cm and a kappa value of lower kappa grating 124 being in a range of 10/cm to 50/cm is a SMSR for laser 100 of at least 40 decibels (dB) (resulting in a ratio of the kappa value of high kappa grating 122 to the kappa value of lower kappa grating 124 being in a range of 1.6 to 20) and being in a range of 10/cm to 55/cm is a SMSR for laser 100 of at least 30 decibels (dB) (resulting in a ratio of the kappa value of high kappa grating 122 to the kappa value of lower kappa grating 124 being in a range of 1.5 to 20).

In embodiments, the kappa value of high kappa grating 122 of grating system 120 is at least 80/cm. In embodiments, the kappa value of high kappa grating 122 of grating system 120 is at least 100/cm. In embodiments, the kappa value of high kappa grating 122 of grating system 120 is in a range of 80/cm to 200/cm. In embodiments, the kappa value of high kappa grating 122 of grating system 120 is at least 80/cm and the kappa value of lower kappa grating 124 of grating system 120 is in a range of 10/cm to 50/cm. In embodiments, the kappa value of high kappa grating 122 of grating system 120 is in a range of 80/cm to 200/cm and the kappa value of lower kappa grating 124 of grating system 120 is in a range of 10/cm to 50/cm. In embodiments, the kappa value of high kappa grating 122 of grating system 120 is in a range of 80/cm to 200/cm and the kappa value of lower kappa grating 124 of grating system 120 is in a range of 20/cm to 40/cm. In embodiments, a ratio of the kappa value of high kappa grating 122 to lower kappa grating 124 of grating system 120 is in a range of 1.5 to 20. In embodiments, a ratio of the kappa value of high kappa grating 122 to lower kappa grating 124 of grating system 120 is in a range of 2 to 20.

As mentioned herein, the above simulations were performed based on the arrangement illustrated in FIG. 5. Similar results may be Obtainable with the arrangement of FIG. 4 wherein lower kappa grating 124 of grating system 120 is a uniform grating and with the arrangement of FIG. 6 wherein lower kappa grating 124 of grating system 120 is a chirped grating. In embodiments, the at least one additional diffraction grating 124 provides a continuously variable pitch between high kappa grating 122 and front facet 112.

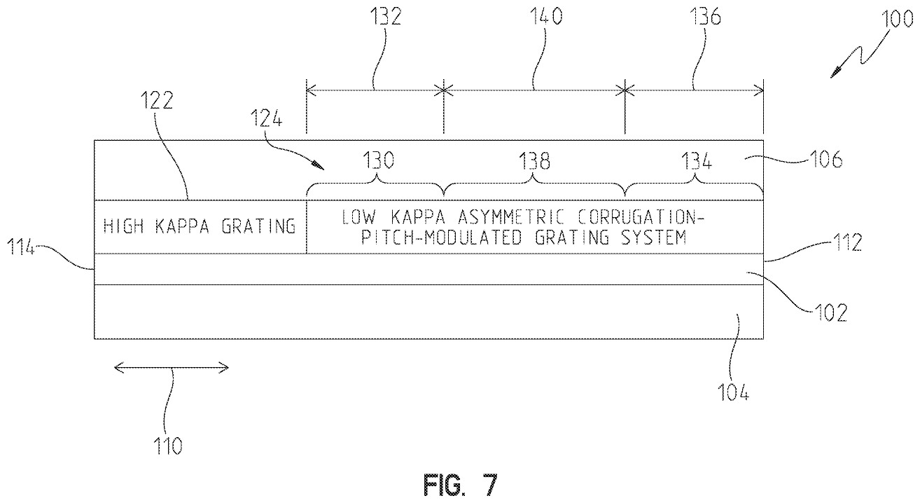

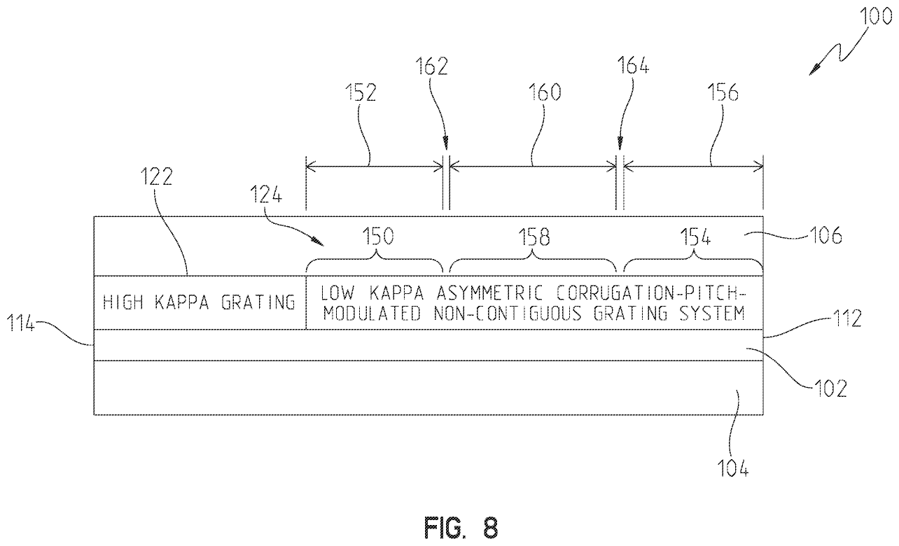

Referring to FIG. 7, laser 100 includes an asymmetric corrugation pitch modulated (ACPM) grating system for lower kappa grating 124. The asymmetric corrugation pitch modulated (ACPM) grating system includes a rear uniform grating 130 positioned proximate high kappa grating 122 and having a longitudinal length 132, a front uniform grating 134 positioned proximate front facet 112 and having a longitudinal length 136, and a grating 138 positioned longitudinally between rear uniform grating 130 and front uniform grating 134 and having a longitudinal length 140. Grating 138 has a different pitch than grating 130 and grating 134. Rear uniform grating 130, grating 138, and front uniform grating 134 are contiguous and the phase is successive between the regions of lower kappa grating 124. In embodiments, high kappa grating 122 has a first pitch, rear uniform grating 130 has a second pitch, grating 138 has a third pitch, and front uniform grating 134 has a fourth pitch, the third pitch being different from the first pitch, the second pitch, and the fourth pitch.

Referring to FIG, 8, laser 100 includes a non-contiguous asymmetric corrugation pitch modulated grating system for lower kappa grating 124. The non-contiguous asymmetric corrugation pitch modulated grating system includes a rear uniform grating 150 positioned proximate high kappa grating 122 and having a longitudinal length 152, a front uniform grating 154 positioned proximate front facet 112 and having a longitudinal length 156, a grating 158 positioned longitudinally between rear uniform grating 150 and front uniform grating 154 and having a longitudinal length 160. Grating 158 has a different pitch than grating 150 and grating 154. fear uniform grating 150 and grating 158 are longitudinally separated by region 162 and front uniform grating 154 and grating 158 are longitudinally separated by region 164. In an example, each of regions 162 and 164 do not include any grating structure. For example, each of regions 162 and 164 may be comprised of the p-type cladding layer material and be void of any grating structure. In another example, each of regions 162 and 164 may include a block of material different than the p-type cladding layer material and also void of any grating structure. As such, rear uniform grating 150 and grating 158 are non-contiguous and front uniform grating 154 and grating 158 are non-contiguous. In embodiments, grating 158 is contiguous with one of rear uniform grating 150 and front uniform grating 154. In embodiments, high kappa grating 122 has a first pitch, rear uniform grating 150 has a second pitch, grating 158 has a third pitch, and front uniform grating 154 has a fourth pitch, the third pitch being different fr©m the first pitch, the second pitch, and the fourth pitch.

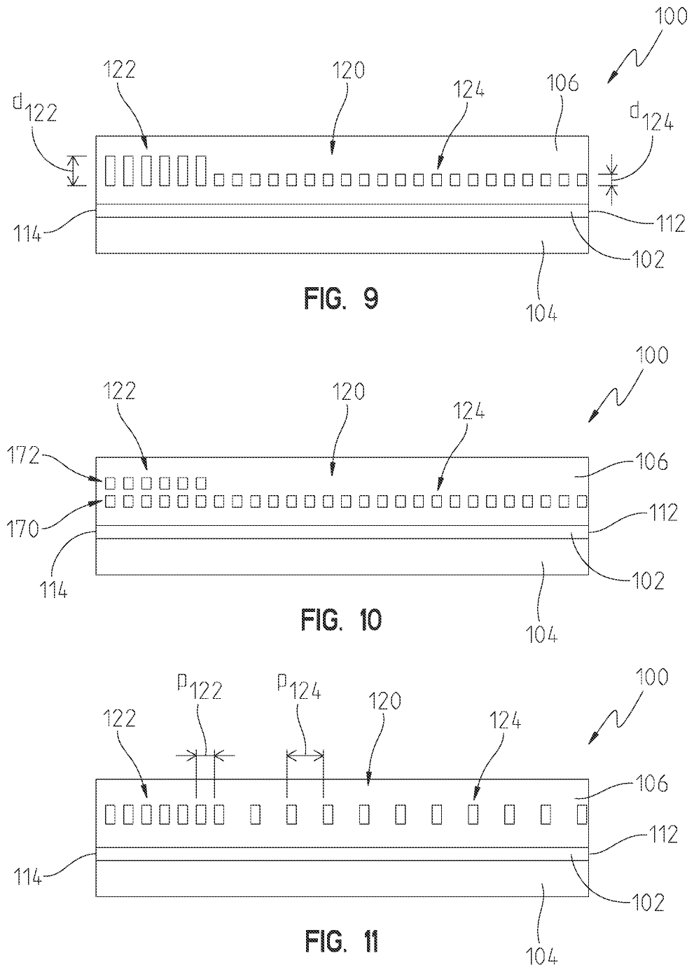

Several structural characteristics of laser 100 may result in the arrangement shown in FIG. 3 of having a high kappa grating 122 proximate rear facet 114 with lower kappa gratings 124 longitudinally between high kappa grating 122 and front facet 112. Examples are provided in FIGS. 9-12. Each of FIGS. 9-12 illustrate an exemplary structure, but the exemplary structures may also be combined in various embodiments.

Referring to FIG. 9, lower kappa gratings 124 is illustrated as a uniform grating. High kappa grating 122 is formed by having a grating with a larger height d₁₂₂ compared to a grating height d₁₂₄ of lower kappa gratings 124. As illustrated, the pitch of each of high kappa grating 122 and lower kappa gratings 124 is the same, but in embodiments, may be different.

Referring to FIG. 10, lower kappa gratings 124 is illustrated as a uniform grating. High kappa grating 122 is formed by having multiple gratings stacked vertically, illustratively grating 170 and grating 172. As illustrated, the pitch of each of high kappa grating 122 and lower kappa gratings 124 is the same, but in embodiments, may be different.

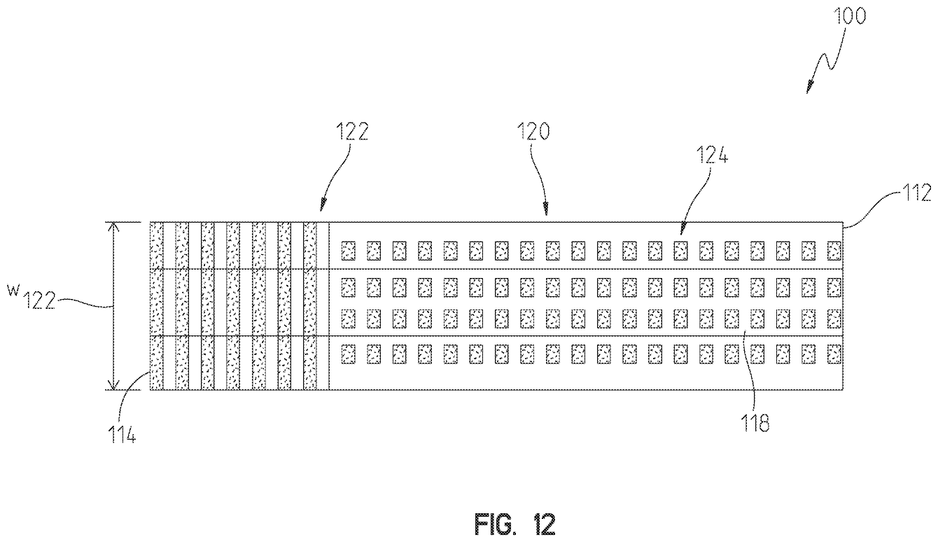

Referring to FIG. 11, higher kappa gratings 122 is illustrated as a uniform grating having a pitch P₁₂₂. Lower kappa grating 124 is formed by having a grating of the same thickness as 122, but with a number of ‘teeth’ removed from the grating to reduce its strength.

Referring to FIG. 12, a plan view, higher kappa gratings 122 is illustrated as a uniform grating having a lateral width of w₁₂₂. Lower kappa grating 124 is formed by having gaps made in the lateral width of the grating teeth so as to reduce the kappa. As shown, in FIG. 12, laser 100 may include a ridge 118 which runs a longitudinal length of laser 100.

An advantage, among others, of the arrangement of laser 100 in the embodiments disclosed herein is that the phase of the reflected light from the rear facet is dictated by the high kappa grating and not by the position of the facet 114 relative to the grating 112. This permits the characteristics of various embodiments of lower kappa gratings 124, such as QWS, uniform, chirped, and others, to be designed to optimize threshold current, slope and other characteristics of laser 100 Further, the known phase may be selected to be tolerant against back reflections from external reflections or increased front facet reflections from index mismatch, for example from epoxy (0% to 4% reflection due to epoxy on front facet 112). The lengths of high kappa grating 122 and lower kappa gratings 124 and the characteristics of each, such as the π phase shift position in a QWS grating, may be selected to optimize laser output power and SMSR.

When solder making electrical connections to laser 100 cools, the thermal expansion mismatch between solder, laser, and submount(s) may introduce a chirp into grating system 120 of laser 100. Another advantage, among others, of being able to control the phase of reflected light from the rear of the laser into active layer 102 with higher kappa gratings 122 is that it can be controlled to account for anticipated chirping introduced during manufacturing, such as due to solder.

While this invention has been described as having exemplary designs, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

I claim:

1. A semiconductor laser, comprising:
an active region having a longitudinal axis, a rear facet end, and a front facet end, the front facet end emitting an output beam of light from the semiconductor laser; and
a plurality of diffraction gratings positioned along the longitudinal axis of the active region, the plurality of diffraction grating including a first diffraction grating positioned proximate the rear facet end of the active region and at least one additional diffraction grating positioned longitudinally between the first diffraction grating and the front facet end, the first diffraction grating having a first kappa value and the at least one additional diffraction grating having at least a second kappa value, the first kappa value being greater than the second kappa value.

2. The semiconductor laser of claim 1, wherein the first kappa value is at least 80/cm.

3. The semiconductor laser of claim 2, wherein the first kappa value is at least 100/cm.

4. The semiconductor laser of claim 1, wherein the first kappa value is in a range of 80/cm to 300/cm and the second kappa value is in a range of 10/cm to 50/cm.

5. The semiconductor laser of claim 4, wherein the second kappa value is in a range of 20/cm to 50/cm.

6. The semiconductor laser of claim 4, wherein the second kappa value is in a range of 20/cm to 40/cm.

7. The semiconductor laser of claim 4, wherein the second kappa value is in a range of 10/cm to 40/cm.

8. The semiconductor laser of claim 1, wherein the first kappa value is at least 80/cm and the second kappa value is in a range of 10/cm to 50/cm.

9. The semiconductor laser of claim 1, wherein a ratio of the first kappa value to the second kappa value is 1.5 to 20.

10. The semiconductor laser of claim 1, wherein a ratio of the first kappa value to the second kappa value is 1.6 to 20.

11. The semiconductor laser of claim 1, wherein a ratio of the first kappa value to the second kappa value is 2 to 20.

12. The semiconductor laser of claim 1, wherein the first diffraction grating is a uniform grating.

13. The semiconductor laser of claim 1, wherein the at least one additional diffraction prating includes a quarter wavelength shift (QWS) grating.

14. The semiconductor laser of claim 1, wherein the at least one additional diffraction grating includes a chirped grating.

15. The semiconductor laser of claim 1, wherein the at least one additional diffraction grating includes an asymmetric corrugation pitch modulated (ACPM) grating system.

16. The semiconductor laser of claim 15, wherein the asymmetric corrugation pitch modulated (ACPM) grating system includes a rear uniform grating positioned longitudinally proximate the first grating, a front uniform grating positioned longitudinally proximate the front facet end, and at least a third grating positioned longitudinally between the rear uniform grating and the front uniform grating, the rear uniform grating, the third grating, and the front uniform grating are contiguous.

17. The semiconductor laser of claim 16, wherein the first grating has a first pitch, the rear uniform grating has a second pitch, the third grating has a third pitch, and the front uniform grating has a fourth pitch, the third pitch being different from the first pitch, the second pitch, and the fourth pitch.

18. The semiconductor laser of claim 1, wherein the at least one additional diffraction grating includes a non-contiguous asymmetric corrugation pitch modulated grating system.

19. The semiconductor laser of claim 18, wherein the non-contiguous asymmetric corrugation pitch modulated grating system includes a rear uniform grating positioned longitudinally proximate the first diffraction grating, a front uniform grating positioned longitudinally proximate the front facet end, and at least a third grating positioned longitudinally between the rear uniform grating and the front uniform grating, at least one of the rear uniform grating and the front uniform grating is longitudinally separated relative to the third grating by a region.

20. The semiconductor laser of claim 19, wherein the first grating has a first pitch, the rear uniform grating has a second pitch, the third grating has a third pitch, and the front uniform grating has a fourth pitch, the third pitch being different from the first pitch, the second pitch, and the fourth pitch.

21. The semiconductor laser of claim 18, wherein the non-contiguous asymmetric corrugation pitch modulated grating system includes a rear uniform grating positioned longitudinally proximate the first diffraction grating, a front uniform grating positioned longitudinally proximate the front facet end, and at least a third grating positioned longitudinally between the rear uniform grating and the front uniform grating, the rear uniform grating and the third grating are longitudinally separated by a first region and the front uniform grating and the third grating are longitudinally separated by a second region.

22. The semiconductor laser of claim 1, wherein the at least one additional diffraction grating provides a continuously variable pitch between the first grating and the front facet.

23. The semiconductor laser of claim 1, further comprising a first reflection coating provided on the front facet end of the active region having a reflectivity of less than 5% and a second reflection coating provided on the rear facet end of the active region having a reflectivity of less than 5%.

24. A semiconductor laser array, comprising:
a semiconductor substrate; and
a plurality of semiconductor lasers formed on the semiconductor substrate; each of the plurality of semiconductor lasers comprising:
an active region having a longitudinal axis, a rear facet end, and a front facet end, the front facet end emitting an output beam of the semiconductor laser; and
a plurality of diffraction gratings positioned along the longitudinal axis of the active region, the plurality of diffraction grating including a first diffraction grating positioned proximate the rear facet end of the active region and at least one additional diffraction grating positioned longitudinally between the first diffraction grating and the front facet end, the first diffraction grating having a first kappa value and the at least one additional diffraction grating having at least a second kappa value, the first kappa value being greater than the second kappa value.
